(19) United States
(12) Patent Application Publication
(10) Pub. No.: US 2014/0339660 A1
(43) Pub. Date: Nov. 20, 2014

(54) MAGNETORESISTIVE ELEMENT AND MEMORY DEVICE INCLUDING THE SAME

(71) Applicants: Sung-chul LEE, Osan-si (KR); Kwang-seok KIM, Seoul (KR); Kee-won KIM, Suwon-si (KR); Young-man JANG, Hwaseong-si (KR); Ung-hwan PI, Seoul (KR)

(72) Inventors: Sung-chul LEE, Osan-si (KR); Kwang-seok KIM, Seoul (KR); Kee-won KIM, Suwon-si (KR); Young-man JANG, Hwaseong-si (KR); Ung-hwan PI, Seoul (KR)

(21) Appl. No.: 14/247,245

(22) Filed: Apr. 7, 2014

(30) Foreign Application Priority Data
May 16, 2013 (KR) 10-2013-0056046

(51) Int. Cl. H01L 43/02; H01L 27/22

(52) U.S. Cl. CPC H01L 43/02; H01L 27/224
USPC 257/421

(57) ABSTRACT

Provided are magnetoresistive elements, memory devices including the same, and an operation methods thereof. A magnetoresistive element may include a free layer, and the free layer may include a plurality of regions (layers) having different properties. The free layer may include a plurality of regions (layers) having different Curie temperatures. The Curie temperature of the free layer may change regionally or gradually away from the pinned layer. The free layer may include a first region having ferromagnetic characteristics at a first temperature and a second region having paramagnetic characteristics at the first temperature. The first region and the second region both may have ferromagnetic characteristics at a second temperature lower than the first temperature. The effective thickness of the free layer may change with temperature.

### CROSS-REFERENCE TO RELATED APPLICATIONS

This application claims the benefit of Korean Patent Application No. 10-2013-0056046, filed on May 16, 2013, in the Korean Intellectual Property Office, the disclosure of which is incorporated herein in its entirety by reference.

### BACKGROUND

The inventive concept relates to magnetoresistive elements and memory devices including the same.

A magnetic random access memory (MRAM) is a memory device that stores data by using resistance change of a magnetoresistive element such as a magnetic tunneling junction (MTJ) element. The resistance of the MTJ element varies according to the magnetization direction of a free layer. That is, when the free layer has the same magnetization direction as a pinned layer, the MTJ element has a low resistance value; and when the free layer has an opposite magnetization direction to the pinned layer, the MTJ element has a high resistance value. When the MTJ element has a low resistance value, it may correspond to data ‘0’, and when the MTJ element has a high resistance value, it may correspond to data ‘1’. The MRAM is nonvolatile and is capable of high-speed operation, and has high endurance. Thus, it is deemed as one of the next-generation nonvolatile memory devices.

Recently, extensive research has been conducted into developing a highly integrated spin transfer torque magnetic random access memory (STT-MRAM), which is one of MRAM devices, as STT-MRAM is advantageous for improving a recording density. However, it is not easy to reduce the intensity of a write current (i.e., switching current) for STT-MRAM while ensuring data retention characteristics (i.e., thermal stability of data) thereof. As the thickness of the free layer of STT-MRAM increases, the retention characteristics (i.e., thermal stability) of data written into the free layer may improve but the intensity of a current (i.e., write current) necessary to write data into the free layer may increase. On the other hand, as the thickness of the free layer decreases, the intensity of a write current may decrease but the data retention characteristics (thermal stability) may degrade. Therefore, it is not easy to implement a magnetic memory device (e.g., STT-MRAM) that has both high data writability (writing easiness) and excellent data retention characteristics (thermal stability).

### SUMMARY

The inventive concept provides magnetoresistive elements having an excellent performance, and magnetic memory devices including the same.

The inventive concept also provides magnetoresistive elements having high writability (easiness in writing) and excellent data retention characteristics, and magnetic memory devices including the same.

The inventive concept also provides magnetoresistive elements having a low write current and excellent thermal stability, and magnetic memory devices including the same.

The inventive concept also provides methods of operating magnetic memory devices including the magnetoresistive elements.

According to an aspect of the inventive concept, there is provided a magnetoresistive element including: a pinned layer having a fixed magnetization direction; and a free layer corresponding to the pinned layer and having a variable magnetization direction, wherein the free layer includes a plurality of regions having different Curie temperatures.

The plurality of regions having different Curie temperatures may be sequentially arranged in a direction perpendicular to the pinned layer.

The Curie temperature of the free layer may decrease regionally or gradually away from the pinned layer.

The free layer may include a first region and a second region, the first region may be closer to the pinned layer than the second region, and the first region may have a higher Curie temperature than the second region.

The free layer may include at least two layers having different Curie temperatures.

The free layer may include a first layer and a second layer, the first layer may be closer to the pinned layer than the second layer, and the first layer may have a higher Curie temperature than the second layer.

The first layer and the second layer may directly contact each other.

The first layer and the second layer may be exchange-coupled to each other.

The magnetoresistive element may further include a non-magnetic layer between the first layer and the second layer.

The first layer and the second layer may be exchange-coupled to each other through the non-magnetic layer therebetween.

The free layer may further include at least one intermediate layer between the first layer and the second layer, and the at least one intermediate layer may have a Curie temperature that is lower than the Curie temperature of the first layer and higher than the Curie temperature of the second layer.

The Curie temperature of the first layer may be about 300° C. or more.

The Curie temperature of the second layer may be about 200° C. or less.

The magnetoresistive element may further include a thermal insulation layer contacting the free layer.

The thermal insulation layer may have a thermal conductivity of about 100 W/mK or less.

The free layer may be disposed between the thermal insulation layer and the pinned layer.

The magnetoresistive element may further include a separation layer between the free layer and the pinned layer.

According to another aspect of the inventive concept, there is provided a magnetic device or an electronic device including the above magnetoresistive element.

According to another aspect of the inventive concept, there is provided a memory device including at least one memory cell, wherein the at least one memory cell includes the above magnetoresistive element.

The at least one memory cell may further include a switching element connected to the magnetoresistive element.

The memory device may be a magnetic random access memory (MRAM).

The memory device may be a spin transfer torque magnetic random access memory (STT-MRAM).

According to another aspect of the inventive concept, there is provided a magnetoresistive element including: a pinned layer having a fixed magnetization direction; and a free layer corresponding to the pinned layer and having a variable magnetization direction, wherein the free layer includes a first region having ferromagnetic characteristics at a first temperature and a second region having paramagnetic characteristics at the first temperature.

The first region and the second region both may have ferromagnetic characteristics at a second temperature lower than the first temperature.

The first region may be closer to the pinned layer than the second region.

The Curie temperature of the free layer may change regionally or gradually away from the pinned layer.

The Curie temperature of the free layer may decrease regionally or gradually away from the pinned layer.

According to another aspect of the inventive concept, there is provided a magnetic device or an electronic device including the above magnetoresistive element.

According to another aspect of the inventive concept, there is provided a memory device including at least one memory cell, wherein the at least one memory cell includes the above magnetoresistive element.

The at least one memory cell may further include a switching element connected to the magnetoresistive element.

The memory device may be a magnetic random access memory (MRAM).

The memory device may be a spin transfer torque magnetic random access memory (STT-MRAM).

According to another aspect of the inventive concept, there is provided a magnetoresistive element including: a pinned layer having a fixed magnetization direction; and a free layer corresponding to the pinned layer and having a variable magnetization direction, wherein an effective thickness of the free layer varies according to temperature.

The free layer may have a first effective thickness at a first temperature and have a second effective thickness at a second temperature.

The first temperature may be higher than the second temperature. In this case, the first effective thickness may be smaller than the second effective thickness.

The first temperature may be equal to a temperature at which data is written into the magnetoresistive element.

The second temperature may be equal to a temperature during retention of the data after the writing of the data into the magnetoresistive element.

According to another aspect of the inventive concept, there is provided a magnetic device or an electronic device including the above magnetoresistive element.

According to another aspect of the inventive concept, there is provided a memory device including at least one memory cell, wherein the at least one memory cell includes the above magnetoresistive element.

According to another aspect of the inventive concept, there is provided a method of operating a magnetic memory device including a pinned layer and a free layer, the method including: changing a first region of the free layer into a paramagnetic material by heating at least the first region of the free layer; magnetizing a second region of the free layer in a first direction; and changing the first region of the free layer into a ferromagnetic material.

The first region and the second region of the free layer may have different Curie temperatures.

The first region of the free layer may have a lower Curie temperature than the second region of the free layer.

The changing of the first region of the free layer into the paramagnetic material may include heating the first region.

The magnetizing of the second region of the free layer in the first direction may include applying a current between the free layer and the pinned layer.

The changing of the first region of the free layer into the ferromagnetic material may include cooling the first region.

The second region of the free layer may be disposed between the first region and the pinned layer.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view illustrating a magnetoresistive element according to an embodiment of the inventive concept;

FIG. 2 is a cross-sectional view illustrating a magnetoresistive element according to another embodiment of the inventive concept;

FIG. 3 is a cross-sectional view illustrating a magnetoresistive element according to another embodiment of the inventive concept;

FIG. 4 is a cross-sectional view illustrating a magnetoresistive element according to another embodiment of the inventive concept;

FIG. 5 is a cross-sectional view illustrating a magnetoresistive element according to another embodiment of the inventive concept;

FIGS. 6A through 6D are cross-sectional views illustrating a method of operating a magnetoresistive element, according to an embodiment of the inventive concept; and

FIG. 7 is a diagram illustrating a memory device including a magnetoresistive element, according to an embodiment of the inventive concept.

### DETAILED DESCRIPTION OF THE EMBODIMENTS

Hereinafter, magnetoresistive elements according to embodiments of the inventive concept, devices (memory devices) including the same, and methods of operating the same will be described in detail with reference to the accompanying drawings. In the drawings, the thicknesses of layers and regions are exaggerated for clarity. Throughout the specification, like reference numerals denote like elements.

As used herein, the term “and/or” includes any and all combinations of one or more of the associated listed items. Expressions such as “at least one of,” when preceding a list of elements, modify the entire list of elements and do not modify the individual elements of the list.

FIG. 1 is a cross-sectional view illustrating a magnetoresistive element according to an embodiment of the inventive concept.

Referring to FIG. 1, the magnetoresistive element may include a pinned layer PL10, a free layer FL10, and a separation layer SL10 disposed between the pinned layer PL10 and the free layer FL10. The separation layer SL10 may be referred to as a barrier layer or a spacer layer. The pinned layer PL10 is a magnetic layer having a fixed magnetization direction. The pinned layer PL10 may include a predetermined ferromagnetic material. For example, the ferromagnetic material may include at least one of cobalt (Co), ferrum (Fe), or nickel (Ni). The ferromagnetic material may further include other elements such as boron (B), chromium (Cr), platinum (Pt), or palladium (Pd). The free layer FL10 is a magnetic layer having a variable magnetization direction. The free layer FL10 may include a ferromagnetic material. For example, the ferromagnetic material may include at least one of Co, Fe, or Ni. The ferromagnetic material may further include other elements such as B, Cr, Pt, and Pd, in addition to Co, Fe, and Ni. The separation layer SL10 may be formed of an insulating material. For example, the separation layer SL10 may include an insulating material, such as magnesium (Mg) oxide or aluminum (Al) oxide. When such material (especially, Mg oxide) is used as the insulating material of the separation layer SL10, a magnetoresistance (MR) ratio may be increased. However, the material of the separation layer SL10 is not limited to an insulating material. In some embodiments, the separation layer SL10 may be formed of a conductive material to form an MRAM device, for example, a spin valve structure. In this case, the separation layer SL10 may include one conductive material (metal) selected from the group consisting of ruthenium (Ru), cuprum (Cu), aluminum (Al), aurum (Au), argentum (Ag), and any combinations thereof. The thickness of the separation layer SL10 may be about 5 nm or less, for example, about 3 nm or less.

The free layer FL10 may include a plurality of regions (layers) having different Curie temperatures Tc. For example, the free layer FL10 may include a first layer (first region) L10 and a second layer (second region) L20, and the first layer L10 and the second layer L20 may have different Curie temperatures Tc. The first layer L10 and the second layer L20 may be arranged in a direction substantially perpendicular to the pinned layer PL10. The first layer L10 may be closer to the pinned layer PL10 than the second layer L20. Thus, the first layer L10 may be disposed between the second layer L20 and the pinned layer PL10. The Curie temperature Tc of the first layer L10 may be higher than the Curie temperature Tc of the second layer L20. That is, the first layer L10 may have a “high” Curie temperature Tc and the second layer L20 may have a “low” Curie temperature Tc. Herein, “high” and “low” may be relative terms. The Curie temperature Tc of the free layer FL10 may decrease in a direction away from the pinned layer PL10. In this embodiment, the Curie temperature Tc of the free layer FL10 may decrease regionally (i.e., by stages) in a direction away from the pinned layer PL10.

The first layer L10 and the second layer L20 may be exchange-coupled to each other. As in this embodiment, when the first layer L10 and the second layer L20 directly contact each other, they may be referred to as being direct-exchange-coupled. That the first layer L10 and the second layer L20 are exchange-coupled may mean that their magnetizations are coupled. In this regard, the magnetization direction of the second layer L20 may depend on the magnetization direction of the first layer L10. When the magnetization of the first layer L10 is a first direction, the magnetization direction of the second layer L20 may be the first direction. Thus, the first layer L10 and the second layer L20 may have substantially the same magnetization direction.

The Curie temperature Tc of the first layer L10 may be about 300° C. or more, for example, about 700° C. or more. The first layer L10 may include a material having a high Fe and/or Co composition ratio. For example, the first layer L10 may include a material such as NiFe, Co₂MnSi, Co₂FeSi, Co₂FeAl, or CoFeB. As another example, the first layer L10 may include Fe-M-M′—B—Si. Herein, M may be at least one of nickel (Ni) or cobalt (Co), and M′ may be one of chrome (Cr), molybdenum (Mo), wolfram (W), vanadium (V), niobium (Nb), tantalum (Ta), titanium (Ti), zirconium (Zr), or hafnium (Hf). For example, Fe-M-M′—B—Si may be Fe—Ni—Mo—B—Si. The Curie temperature Tc of NiFe may be about 800° C., the Curie temperature Tc of Co₂MnSi may be about 712° C., the Curie temperature Tc of Co₂FeSi may be about 827° C., the Curie temperature Tc of the Co₂FeAl may be about 707° C., and the Curie temperature Tc of CoFeB may be about 1040° C. The Curie temperature Tc of Fe-M-M′—B—Si may be about 360° C. or more, and the Curie temperature Tc of Fe-M-M′—B—Si may be adjusted according to composition. CoFeB may have perpendicular magnetic anisotropy or in-plane magnetic anisotropy, and NiFe, Co₂MnSi, Co₂FeSi, and Co₂FeAl may have in-plane magnetic anisotropy. The above materials of the first layer L10 are merely exemplary, and other various materials may also be used.

The Curie temperature Tc of the second layer L20 may be about 200° C. or less, for example, about 50° C. to about 200° C. The second layer L20 may include a material, such as CoFeTb, Co₂TiAl, Co₂TiSi, Co₂TiGe, or Co₂TiSn. The Curie temperature Tc of CoFeTb may be about 100° C., the Curie temperature Tc of Co₂TiAl may be about −153° C., the Curie temperature Tc of Co₂TiSi may be about 107° C., the Curie temperature Tc of the Co₂TiGe may be about 107° C., and the Curie temperature Tc of Co₂TiSn may be about 82° C. The Curie temperature Tc of the CoFeTb may be adjusted according to composition. CoFeTb may have perpendicular magnetic anisotropy, and Co₂TiAl, Co₂TiSi, Co₂TiGe, and Co₂TiSn may have in-plane magnetic anisotropy. The above materials of the second layer L20 are merely exemplary, and other various materials may also be used.

Since the Curie temperature Tc of the second layer L20 is low, when the temperature of the free layer FL10 is increased by Joule's heat in a write operation for writing data into the free layer FL10, the second layer L20 may have paramagnetic characteristics or non-magnetic characteristics. That is, in the write operation, when the temperature of the free layer FL10 increases, the second layer L20 may lose ferromagnetic characteristics and have paramagnetic characteristics or non-magnetic characteristics. On the other hand, since the Curie temperature Tc of the first layer L10 is high, the first layer L10 may retain ferromagnetic characteristics in the write operation. Thus, in the write operation, the effective thickness of the free layer FL10 may be equal to or similar to the thickness of the first layer L10. Thus, the intensity of a current (i.e., write current) necessary to write data may be reduced.

After the write operation, when the temperature of the free layer FL10 becomes lower than the Curie temperature Tc of the second layer L20, the second layer L20 may have ferromagnetic characteristics. In this case, the magnetization of the second layer L20 may be determined by the magnetization of the first layer L10. That is, the magnetization direction of the second layer L20 may be set to be equal to the magnetization direction of the first layer L10. Also, the effective thickness of the free layer FL10 may be substantially equal to or similar to the sum of the thickness of the first layer L10 and the thickness of the second layer L20. In this manner, since the effective thickness of the free layer FL10 is large in data retention, the data retention characteristics (i.e., thermal stability) of the free layer FL10 may be excellent.

With the free layer FL10 having a plurality of regions (layers) L10 and L20 having different Curie temperatures Tc, the effective thickness of the free layer FL10 in the write operation may be reduced and the effective thickness of the free layer FL10 after the write operation may be increased. Accordingly, it may be possible to implement a magnetoresistive element that has high data writability (i.e., low write current) and excellent data retention characteristics (i.e., thermal stability).

On the other hand, in a read operation for reading data written into the free layer FL10, the data written into the free layer FL10 may be distinguished by measuring the resistance between the free layer FL10 and the pinned layer PL10, specifically the resistance between the first layer L10 of the free layer FL10 and the pinned layer PL10. When the first layer L10 has the same magnetization direction as the pinned layer PL10, a low resistance may be measured; and when the first layer L10 has an opposite magnetization direction to the pinned layer PL10, a high resistance may be measured. The low resistance may correspond to data ‘0’ and the high resistance may correspond to data ‘1’, or vice versa.

FIG. 2 is a cross-sectional view illustrating a magnetoresistive element according to another embodiment of the inventive concept.

Referring to FIG. 2, a free layer FL10′ may include a first layer L10 and a second layer L20. A non-magnetic layer N15 may be disposed between the first layer L10 and the second layer L20. In this case, the first layer L10 and the second layer L20 may be exchange-coupled to each other through the non-magnetic layer N15 therebetween. In this case, the first layer L10 and the second layer L20 may be referred to as being interlayer-exchange-coupled by the non-magnetic layer N15. Thus, the magnetization direction of the second layer L20 may depend on the magnetization direction of the first layer L10.

The non-magnetic layer N15 may include a conductive material. For example, the non-magnetic layer N15 may include one conductive material (metal) selected from the group consisting of Ru, Cu, Al, Au, Ag, and any combinations thereof. The thickness of the non-magnetic layer N15 may be about 3 nm or less, for example, about 2 nm or less. Other components besides the non-magnetic layer N15 in FIG. 2 may be identical to or similar to those described with reference to FIG. 1.

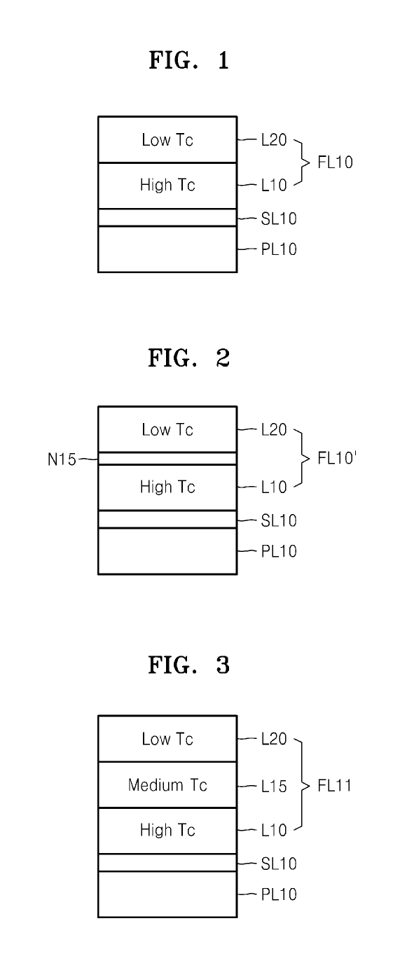

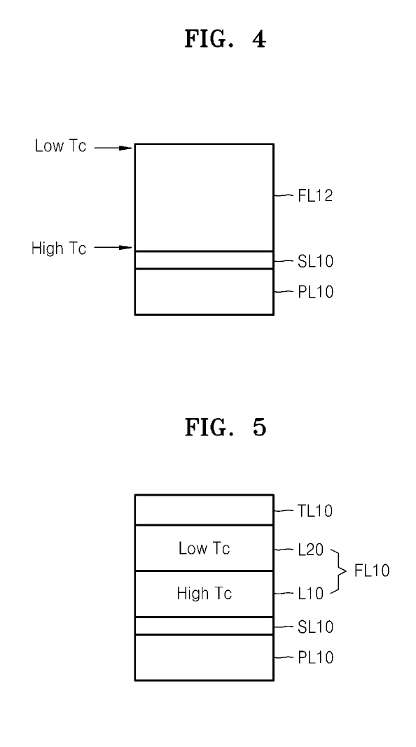

FIG. 3 is a cross-sectional view illustrating a magnetoresistive element according to another embodiment of the inventive concept.

Referring to FIG. 3, a free layer FL11 may further include an intermediate layer L15 between a first layer L10 and a second layer L20. The Curie temperature Tc of the intermediate layer L15 may be lower than the Curie temperature Tc of the first layer L10 and higher than the Curie temperature Tc of the second layer L20. Thus, the intermediate layer L15 may have a “medium” Curie temperature Tc. The intermediate layer L15 may be exchange-coupled with the first layer L10 and the second layer L20. In a write operation, both the intermediate layer L15 and the second layer L20 may be changed to have paramagnetic or non-magnetic characteristics, or only the second layer L20 may be changed to have paramagnetic or non-magnetic characteristics. After the write operation, the first layer L10, the intermediate layer L15, and the second layer L20 may all have ferromagnetic characteristics.

Although only one intermediate layer L15 is illustrated in FIG. 3, two or more intermediate layers may be used. In this case, the Curie temperatures Tc of the two more intermediate layers may decrease from the first layer L10 toward the second layer L20.

FIG. 4 is a cross-sectional view illustrating a magnetoresistive element according to another embodiment of the inventive concept.

Referring to FIG. 4, the Curie temperature Tc of a free layer FL12 may gradually change in the thickness direction of the free layer FL12. For example, the Curie temperature Tc of the free layer FL12 may gradually decrease in a direction away from a pinned layer PL10. Thus, a lower region of the free layer FL12 closer to the pinned layer PL10 may have a “high” Curie temperature Tc, and an upper region of the free layer FL12 may have a “low” Curie temperature Tc. As in this embodiment, even in the case where the Curie temperature Tc of the free layer FL12 gradually changes, in a write operation, the upper region of the free layer FL12 may be changed to have paramagnetic or non-magnetic characteristics (by Joule's heat) and the lower region of the free layer FL12 may retain ferromagnetic characteristics. After the write operation, substantially the entire free layer FL12 may have ferromagnetic characteristics. A structure of the free layer FL12 of FIG. 4 may be obtained by gradually changing a source material (gas) and/or a formation condition during formation of the free layer FL12.

The magnetoresistive elements of FIGS. 1 through 4 may further include thermal insulation layers contacting the free layers FL10, FL10′, FL11, and FL12, respectively. An example thereof is illustrated in FIG. 5.

FIG. 5 is a cross-sectional view illustrating a magnetoresistive element according to another embodiment of the inventive concept. This embodiment corresponds to the case of applying a thermal insulation layer TL10 to the structure of FIG. 1.

Referring to FIG. 5, the thermal insulation layer TL10 may contact a free layer FL10. The thermal insulation layer TL10 may contact a second layer L20 of the free layer FL10. The thermal insulation layer TL10 may face a first layer L10 with the second layer L20 therebetween. Also, the thermal insulation layer TL10 may face a pinned layer PL10 with the free layer FL10 therebetween. The thermal insulation layer TL10 may have a relatively low thermal conductivity. Thus, the thermal insulation layer TL10 may be referred to as a low thermal conductivity layer. The thermal conductivity of the thermal insulation layer TL10 may be about 100 W/mK or less, for example, about 80 W/mK or less. For example, the thermal insulation layer TL10 may be formed of titanium (Ti), rhenium (Re), indium (In), tantalum (Ta), platinum (Pt), TaN, or TiN. By disposing the thermal insulation layer TL10 to contact the second layer L20, the temperature of the second layer L20 may be easily increased in a write operation. Thus, in the write operation, the second layer L20 may be easily induced to change into a paramagnetic or non-magnetic material.

In addition, the thermal insulation layer TL10 may be an electrically conductive material. That is, the thermal insulation layer TL10 may have an electrical conductivity of a general metal level or more. Thus, an electrical signal (current/voltage) may be easily applied through the thermal insulation layer TL10 to the free layer FL10. When the electrical resistivity of a material constituting the thermal insulation layer TL10 is somewhat high, the electrical resistance of the entire thermal insulation layer TL10 may be reduced by forming the thermal insulation layer TL10 to a small thickness (e.g., 10 nm or less thickness). Thus, even a material having a somewhat high electrical resistivity (e.g., TaN or TiN) may be used as the material of the thermal insulation layer TL10.

FIG. 5 illustrates the case of applying the thermal insulation layer TL10 to the structure of FIG. 1. However, the thermal insulation layer TL10 may also be similarly applied to the structures of FIGS. 2 through 4.

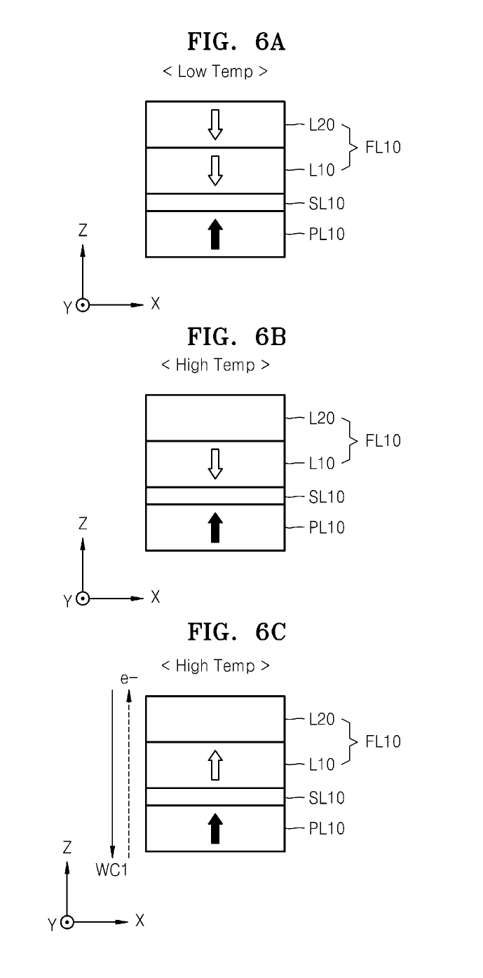

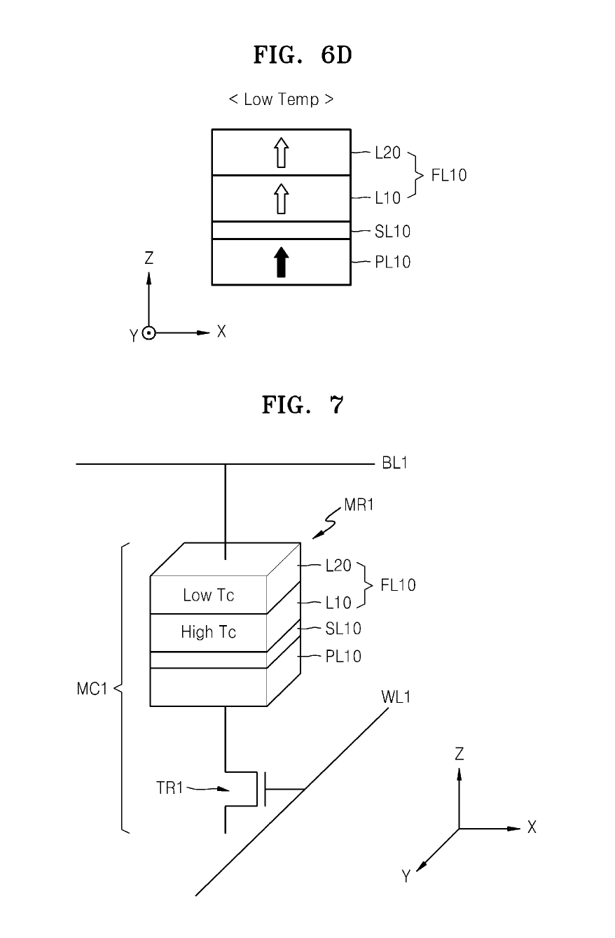

FIGS. 6A through 6D are cross-sectional views illustrating a method of operating a magnetoresistive element, according to some embodiments of the inventive concept. This embodiment relates to the magnetoresistive element of FIG. 1.

FIG. 6A illustrates an exemplary initial state. Referring to FIG. 6A, the pinned layer PL10 may have a magnetization direction fixed in a Z-axis direction. The first layer L10 and the second layer L20 of the free layer FL10 may be magnetized in the opposite direction of the Z axis. The state of the first layer L10 being magnetized in the opposite direction of the pinned layer PL10 may be referred to as an anti-parallel state, and the magnetoresistive element may have a high resistance in this state. The magnetoresistive element of FIG. 6A may be in a low-temperature state. The low temperature may be lower than the Curie temperatures Tc of the first layer L10 and the second layer L20. For example, the low temperature may be about 100° C. or less. In this low-temperature state, the first layer L10 and the second layer L20 may both have ferromagnetic characteristics and may have the same magnetization direction due to exchange-coupling characteristics.

Referring to FIG. 6B, a high-temperature state may be provided by increasing the temperature of the free layer FL10. In this case, the high temperature may be higher than the Curie temperature Tc of the second layer L20 and lower than the Curie temperature Tc of the first layer L10. For example, the high temperature may be about 100° C. or more. Thus, at the high temperature, the second layer L20 may change from a ferromagnetic state to a paramagnetic or non-magnetic state. Thus, the second layer L20 may lose magnetization characteristics of being magnetized in a predetermined direction. On the other hand, the first layer L10 having a high Curie temperature Tc may retain ferromagnetic characteristics. In this case, the effective thickness of the free layer FL10 may be equal to or similar to the thickness of the first layer L10. An increase in the temperature of the free layer FL10 in this operation may be due to Joule's heat caused by a write current (not illustrated) that is applied to the magnetoresistive element. An increase in the temperature of the free layer FL10 in this operation may be caused by a write current WC1 or a similar current thereto, and the write current WC1 will be described with reference to FIG. 6C.

Referring to FIG. 6C, the magnetization direction of the first layer L10 may be reversed (switched) by applying a write current WC1 to the magnetoresistive element. The write current WC1 may be applied from the free layer FL10 to the pinned layer PL10. That is, the write current WC1 may flow from the free layer FL10 through the separation layer SL10 to the pinned layer PL10. By the write current WC1, electrons (e-) may flow from the pinned layer PL10 to the free layer FL10. The electrons (e-) flowing from the pinned layer PL10 to the free layer FL10 may apply a spin torque to the first layer L10 of the free layer FL10 while have the same spin direction as the pinned layer PL10. Accordingly, the first layer L10 of the free layer FL10 may be magnetized in the same direction as the pinned layer PL10. The state of the first layer L10 being magnetized in the same direction of the pinned layer PL10 may be referred to as a parallel state, and the magnetoresistive element may have a low resistance in this state.

In the operation described with reference to FIG. 6C, since the effective thickness of the free layer FL10 may be equal to or similar to the thickness of the first layer L10, data may be easily written into the free layer FL10. That is, it may be possible to reduce the intensity of a current necessary to write data, that is, the write current WC1 necessary to reverse the magnetization of the first layer L10.

FIG. 6D illustrates a case where the temperature of the magnetoresistive element decreases to a low-temperature state after a write operation. Herein, the low-temperature state may be equal to or similar to the low-temperature state described with reference to FIG. 6A. Referring to FIG. 6D, the second layer L20 may restore the ferromagnetic characteristics. Accordingly, exchange coupling may occur between the first layer L10 and the second layer L20, and consequently, the second layer L20 may be magnetized in the same direction as the first layer L10. That is, the first layer L10 and the second layer L20 may both have a magnetization state in the Z-axis direction. In this case, the effective thickness of the free layer FL10 may be equal to or similar to the sum of the thickness of the first layer L10 and the thickness of the second layer L20. In this manner, since the effective thickness of the free layer FL10 is large, the data retention characteristics (i.e., thermal stability) of the free layer FL10 may be excellent.

When the first layer L10 and the second layer L20 of the free layer FL10 are magnetized in the same direction as the pinned layer PL10 in the operation described with reference to FIG. 6A, the magnetization direction of the first layer L10 may be reversed (switched) to an opposite direction to the magnetization direction of the pinned layer PL10 by applying a write current (second write current) of an opposite direction to the write current WC1, that is, a write current (second write current) flowing from the pinned layer PL10 to the free layer FL10, in the operation described with reference to FIG. 6C. By the second write current, electrons may flow from the free layer FL10 to the pinned layer PL10. By the electrons flowing from the free layer FL10 to the pinned layer PL10, the first layer L10 may be magnetized in the opposite direction to the pinned layer PL10. This is because, among the electrons flowing to the pinned layer PL10, the electrons having the same spin as the pinned layer PL10 flow to the outside through the pinned layer PL10, but the electrons having the opposite spin to the pinned layer PL10 return to the first layer L0 and apply a spin torque thereto. That is, since the electrons having the opposite spin to the pinned layer PL10 apply a spin torque to the first layer L10, the first layer L10 may be magnetized in the opposite direction to the pinned layer PL10.

As described with reference to FIGS. 6A through 6D, the magnetization direction of the free layer FL10 may be reversed (switched) by the write current WC1. Since the spin torque of the electrons is transferred to the free layer FL10 by the write current WC1, the free layer FL10 may be magnetized in a predetermined direction, that is, the same direction as the magnetization direction of the pinned layer PL10 or the opposition direction to the magnetization direction of the pinned layer PL10. Thus, the free layer FL10 may be referred to as being magnetized by a spin transfer torque (STT).

The operation method of FIGS. 6A through 6D relates to the structure of FIG. 1. However, this method may also be similarly applied to the structures of FIGS. 2 through 5. The embodiment of FIGS. 6A through 6D illustrates the case where the free layer FL10 and the pinned layer PL10 have perpendicular magnetic anisotropy. However, the free layer FL10 and the pinned layer PL10 may also have in-plane magnetic anisotropy.

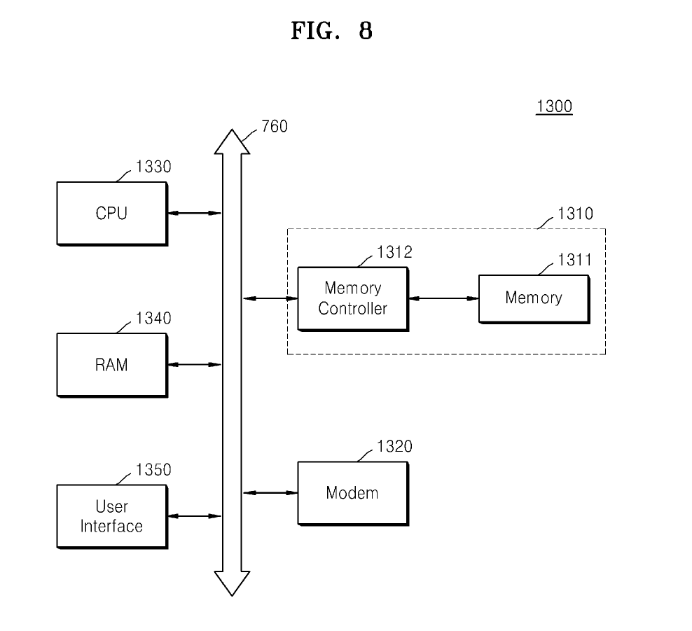

FIG. 7 is a diagram illustrating an example of a memory device including a magnetoresistive element MR1 according to an embodiment of the inventive concept.

Referring to FIG. 7, the memory device according to this embodiment may include a memory cell MC1 including the magnetoresistive element MR1 and a switching element TR1 connected to the magnetoresistive element MR1. The magnetoresistive element MR1 may have any one of the structures of FIGS. 1 through 5, for example, the structure of FIG. 1. The switching element TR1 may be, for example, a transistor. In particular, the switching element TR1 may be a diode, a pnp bipolar transistor, an npn bipolar transistor, an NMOS field effect transistor (FET), or a PMOS FET. If the switching element TR1 is a three-terminal switching device, such as a bipolar transistor and/or MOSFET, an additional interconnection line (not shown) may be connected to the switching element TR1.

The memory cell MC1 may be connected between a bit line BL1 and a word line WL1. The bit line BL1 and the word line WL1 may intersect each other, and the memory cell MC1 may be disposed at an intersection therebetween. The bit line BL1 may be connected to the magnetoresistive element MR1. The free layer FL10 of the magnetoresistive element MR1 may be electrically connected to the bit line BL1. The pinned layer PL10 may be electrically connected to the word line WL1. The switching element TR1 may be disposed between the pinned layer PL10 and the word line WL1. When the switching element TR1 is a transistor, the word line WL1 may be connected to a gate electrode of the switching element TR1. A write current, a read current, and an erase current may be applied to the memory cell MC1 through the word line WL1 and the bit line BL1.

Only one memory cell MC1 is illustrated in FIG. 7. However, a plurality of memory cells MC1 may be arranged to form an array. That is, a plurality of bit lines BL1 may be arranged to intersect a plurality of word lines WL1, and a plurality of memory cells MC1 may be disposed at respective intersections therebetween. According to an embodiment of the inventive concept, since the magnetoresistive element MR1 has a low write current and excellent data retention characteristics (i.e., thermal stability), the memory cell using the same may have high writability and excellent data retention characteristics.

The memory device of FIG. 7 may be a magnetic random access memory (MRAM). Particularly, since the above-described spin transfer torque may be used in the memory device of FIG. 7, the memory device may be a spin transfer torque MRAM (STT-MRAM). Since the STT-MRAM, unlike a conventional MRAM, may not need a separate conductive line (i.e., digit line) for generating an external magnetic field, it may be advantageous for high integration and an operation method thereof may be simple.

In FIG. 7, the magnetoresistive element MR1 may be turned upside down. In this case, the free layer FL10 of the magnetoresistive element MR1 may be connected to the switching element TR1, and the pinned layer PL10 may be connected to the bit line BL1. In FIG. 7, the magnetoresistive element MR1 is illustrated as having a substantially rectangular shape. However, the magnetoresistive element MR1 may have various shapes such as a circle and an ellipse in plan view. In addition, the structure of FIG. 7 may be modified in various ways.

The operation principle of the memory device of FIG. 7 may be substantially the same as described with reference to FIGS. 6A through 6D. That is, the operation method of FIGS. 6A through 6D may also be similarly applied to the memory device of FIG. 7. For example, after the second layer L20 is changed into a paramagnetic state, the magnetization of the first layer L10 may be reversed (switched) and the second layer L20 may be changed into a ferromagnetic state. The operation method of the memory device of FIG. 7 may be easily understood from FIGS. 6A through 6D, and thus a detailed description thereof is omitted herein.

In addition, the Curie temperature described in the above embodiments is different from a Neel temperature and is also different from a temperature coefficient of a saturation field (Hsat). Thus, the Curie temperature may not correspond to the Neel temperature and the temperature coefficient of a saturation field (Hsat). Also, the second layer L20 is not an antiferromagnetic layer, and may be a ferromagnetic layer having ferromagnetic characteristics in a predetermined temperature range.

The principles of the present disclosure can be applied to either in-plane and perpendicular STT-RAM devices or to combinations of in-plane and perpendicular STT-RAM devices (e.g., devices in which the free layer has a high perpendicular anisotropy while the equilibrium magnetic moment of the free layer remains in-plane). One example of such a device may be seen in U.S. Pat. No. 6,992,359, the contents of which are incorporated herein by reference in their entirety.

A synthetic anti-ferromagnetic (SAF) structure may be used for the pinned layer PL10 or for the free layer FL10 in the above-described magnetoresistive elements within the spirit and scope of the present disclosure.

Although many details have been described above, they should be considered in a descriptive sense only and not for purposes of limitation. For example, those skilled in the art will understand that the structures of the magnetoresistive elements of FIGS. 1 through 5 may be modified variously. For example, the structures of FIGS. 1 through 5 may be turned upside down. The structures of FIGS. 1 through 5 may have various shapes such as a rectangle, a circle, and an ellipse in plan view, and may further include an additional layer for fixing the magnetization direction of the pinned layer PL10. Also, a separate temperature control element (heating element) may be further provided to control the temperatures of the free layers FL10, FL10′, FL11, and FL12. In addition, the magnetoresistive element according to the embodiment of the inventive concept may be applied not only to the memory device as illustrated in FIG. 7, but also to any other memory devices having different structures and any other magnetic devices (electronic devices). Therefore, the scope of the inventive concept is defined not by the detailed description of the embodiments but by the technical concept of the appended claims, and all differences within the scope will be construed as being included in the inventive concept.

In some embodiments, the inventive concept of the present disclosure may be applied to the formation of system-on-chip (SOC) devices requiring a cache. In such cases, the SOC devices may include a magnetoresistive element formed according to the present disclosure coupled to a microprocessor.

Further, the principles of the present disclosure can be applied to other magnetoresistive structures such as dual MTJ (magnetic tunnel junction) structures, where there are two pinned layers (or reference layers) with a free layer sandwitched therebetween.

FIG. 8 is a schematic block diagram illustrating an example of information processing systems including a magnetoresistive element according to example embodiments of the present disclosure.

Referring to FIG. 8, an information processing system 1300 includes a memory system 1310, which may include a magnetoresistive element according to example embodiments of the inventive concept. The information processing system 1300 also includes a modem 1320, a central processing unit (CPU) 1330, a RAM 1340, and a user interface 1350, which may be electrically connected to the memory system 1310 via a system bus 1360. The memory system 1310 may include a memory device 1311 and a memory controller 1312 controlling an overall operation of the memory device 1311. Data processed by the CPU 1330 and/or input from the outside may be stored in the memory system 1310. Here, the memory system 1310 may constitute a solid state drive SSD, and thus, the information processing system 1300 may be able to store reliably a large amount of data in the memory system 1310. Although not shown in the drawing, it will be apparent to those of ordinary skill in the art that the information processing system 1300 may be also configured to include an application chipset, a camera image processor (CIS), and/or an input/output device.

While the inventive concept has been particularly shown and described with reference to exemplary embodiments thereof, it will be understood that various changes in form and details may be made therein without departing from the spirit and scope of the following claims.

What is claimed is:

1. A magnetoresistive element comprising:
a pinned layer having a fixed magnetization direction; and
a free layer corresponding to the pinned layer and having a variable magnetization direction,
wherein the free layer comprises a plurality of regions having different Curie temperatures.

2. The magnetoresistive element of claim 1, wherein the plurality of regions having different Curie temperatures are sequentially arranged in a direction perpendicular to the pinned layer.

3. The magnetoresistive element of claim 1, wherein the Curie temperature of the free layer decreases regionally or gradually in a direction away from the pinned layer.

4. The magnetoresistive element of claim 1, wherein the free layer comprises at least two layers having different Curie temperatures.

5. The magnetoresistive element of claim 4, wherein
the free layer comprises a first layer and a second layer,
the first layer is closer to the pinned layer than the second layer, and
the first layer has a higher Curie temperature than a Curie temperature of the second layer.

6. The magnetoresistive element of claim 5, wherein the first layer and the second layer directly contact each other.

7. The magnetoresistive element of claim 5, further comprising a non-magnetic layer between the first layer and the second layer,
wherein the first layer and the second layer are exchange-coupled to each other through the non-magnetic layer therebetween.

8. The magnetoresistive element of claim 5, wherein
the free layer further comprises at least one intermediate layer between the first layer and the second layer, and
the at least one intermediate layer has a Curie temperature lower than the Curie temperature of the first layer and higher than the Curie temperature of the second layer.

9. The magnetoresistive element of claim 1, further comprising a thermal insulation layer contacting the free layer,
wherein the thermal insulation layer has a thermal conductivity of about 100 W/mK or less.

10. The magnetoresistive element of claim 1, further comprising a separation layer between the free layer and the pinned layer.

11. A memory device comprising at least one memory cell, wherein the at least one memory cell comprises the magnetoresistive element of claim 1.

12. A magnetoresistive element comprising:
a pinned layer having a fixed magnetization direction; and
a free layer corresponding to the pinned layer and having a variable magnetization direction,
wherein the free layer comprises a first region having ferromagnetic characteristics at a first temperature and a second region having paramagnetic characteristics at the first temperature.

13. The magnetoresistive element of claim 12, wherein the first region and the second region both have ferromagnetic characteristics at a second temperature lower than the first temperature.

14. The magnetoresistive element of claim 12, wherein the first region is closer to the pinned layer than the second region.

15. The magnetoresistive element of claim 12, wherein the Curie temperature of the free layer changes regionally or gradually in a direction away from the pinned layer.

16. A memory device comprising at least one memory cell, wherein the at least one memory cell comprises the magnetoresistive element of claim 12.

17. A device comprising:
a pinned layer having a fixed magnetization direction;
a free layer; and
a separation layer disposed between the pinned layer and the free layer,
wherein the free layer comprises a first layer and a second layer, the first layer and the second layer having different Curie temperatures.

18. The device of claim 1, wherein the first layer is closer to the pinned layer than the second layer.

19. The device of claim 17, wherein the Curie temperature of the first layer is higher than the Curie temperature of the second layer.
